(19) United States
(12) Patent Application Publication
(10) Pub. No.: US 2010/0071939 A1
(43) Pub. Date: Mar. 25, 2010

(54) Substrate of window ball grid array package

(76) Inventors: Hung-Hsiang Cheng, Kaohsiung (TW); Chih-Yi Huang, Kaohsiung (TW); Chi-Tsung Chiu, Kaohsiung (TW); Ta-Chun Lee, Kaohsiung (TW)

Correspondence Address: MCCRACKEN & FRANK LLP, 311 S. WACKER DRIVE, SUITE 2500, CHICAGO, IL, 60606, US

(21) Appl. No.: 12/584,084

(22) Filed: Aug. 31, 2009

(30) Foreign Application Priority Data
Sep. 25, 2008 (TW) 097136947

(51) Int. Cl. H05K 1/02

(52) U.S. Cl. 174/257; 174/262

(57) ABSTRACT

The present invention relates to a substrate of a window ball grid array package. The substrate includes at least one window, a first conductive layer, a second conductive layer, a dielectric layer, a plurality of first vias and a plurality of second vias. The window penetrates the substrate. The first conductive layer has a plurality of fingers and at least one first power/ground plane, and the fingers are disposed at the periphery of the window. The second conductive layer has at least one second power/ground plane. The dielectric layer is disposed between the first conductive layer and the second conductive layer. The first vias electrically connect the first power/ground plane to the second power/ground plane. The second vias are disposed between the fingers and the window, and electrically connect some of the fingers to the second power/ground plane. Thus, the substrate can control the characteristic impedance and increase the signal integrity.

### BACKGROUND OF THE INVENTION

1. Field of the Invention

The present invention relates to a substrate of a package, and more particularly to a substrate of a window ball grid array package.

2. Description of the Related Art

FIG. 1 shows a top view of a conventional substrate of a window ball grid array package, wherein a solder mask is omitted. FIG. 2 shows a cross-sectional view along line 2-2 in FIG. 1, wherein solder balls and wires are added. FIG. 3 shows a cross-sectional view along line 3-3 in FIG. 1, wherein solder balls and wires are added. The substrate 1 comprises at least one window 11, a first conductive layer 12, a second conductive layer 13 (as shown in FIGS. 2 and 3), a dielectric layer 14 (as shown in FIGS. 2 and 3), a plurality of first vias 15A and a plurality of second vias 15B.

The window 11 penetrates the substrate 1, and the window 11 is rectangular. The first conductive layer 12 has at least one first power/ground plane 122, a plurality of I/O ball pads 16, a plurality of power/ground ball pads 17, a plurality of fingers (a plurality of first fingers 121A and a plurality of second fingers 121B) and a plurality of conductive traces (a plurality of first conductive traces 18A and a plurality of second conductive traces 18B).

The material of the first power/ground plane 122 is copper. The power/ground ball pads 17 are disposed on the first power/ground plane 122. A plurality of solder balls 19 (as shown in FIGS. 2 and 3) are formed on the I/O ball pads 16 and the power/ground ball pads 17. The fingers (the first fingers 121A and the second fingers 121B) are disposed at the periphery of the window 11, and are electrically connected to a chip (not shown) by a plurality of wires 20 (as shown in FIGS. 2 and 3). The first fingers 121A are electrically connected to the I/O ball pads 16 by the first conductive traces 18A. The second fingers 121B are electrically connected to the second vias 15B by the second conductive traces 18B.

The second conductive layer 13 has at least one second power/ground plane 131 (as shown in FIGS. 2 and 3). The material of the second power/ground plane 131 is copper. The dielectric layer 14 is disposed between the first conductive layer 12 and the second conductive layer 13. The first vias 15A penetrate the dielectric layer 14 and electrically connect the first power/ground plane 122 to the second power/ground plane 131. The second vias 15B penetrate the dielectric layer 14 and electrically connect the second conductive traces 18B and the second fingers 121B to the second power/ground plane 131.

FIGS. 2 and 3 show schematic views of the conventional substrate of a window ball grid array package during operation. First, FIG. 2 shows a schematic view of a current of a signal. When the chip (not shown) sends out a signal, the current of the signal is transmitted to the first fingers 121A by the wires 20, then to the I/O ball pads 16 by the first conductive traces 18A, and finally out by the solder balls 19.

FIG. 3 shows a schematic view of a return current. The return current is transmitted to the power/ground ball pads 17 by the solder balls 19, and then to the second power/ground plane 131 of the second conductive layer 13 by the first power/ground plane 122 of the first conductive layer 12 and the first vias 15A. Afterward, the return current is transmitted to the first conductive layer 12 by the second vias 15B, then to the second fingers 121B by the second conductive traces 18B, and finally back to the chip by the wires 20.

The conventional substrate 1 of a window ball grid array package has the following disadvantage. Although the second conductive layer 13 is a good conductor with a wide area, which provides a path with low impedance for the return current, and thus is an ideal reference plane for the signal, the second vias 15B are disposed at the periphery of the substrate 1, close to the solder balls 19 and far from the second fingers 121B. Therefore, the return current has to be transmitted back to the second conductive traces 18B of the first conductive layer 12 through the second vias 15B rather than the second conductive layer 13, which provides a path with low impedance. Thus, the return current produces higher impedance, which has bad influences on the electrical property of the substrate 1.

Therefore, it is necessary to provide a substrate of a window ball grid array package to solve the above problem.

### SUMMARY OF THE INVENTION

The present invention is directed to a substrate of a window ball grid array package. The substrate comprises at least one window, a first conductive layer, a second conductive layer, a dielectric layer, a plurality of first vias and a plurality of second vias. The window penetrates the substrate. The first conductive layer has a plurality of fingers and at least one first power/ground plane, and the fingers are disposed at the periphery of the window. The second conductive layer has at least one second power/ground plane. The dielectric layer is disposed between the first conductive layer and the second conductive layer. The first vias penetrate the dielectric layer and electrically connect the first power/ground plane to the second power/ground plane. The second vias penetrate the dielectric layer. The second vias are disposed between the fingers and the window, and electrically connect some of the fingers to the second power/ground plane. Thus, the substrate can control the characteristic impedance and increase the signal integrity.

### BRIEF DESCRIPTION OF THE DRAWINGS

FIG. 1 is a top view of a conventional substrate of a window ball grid array package, wherein a solder mask is omitted;

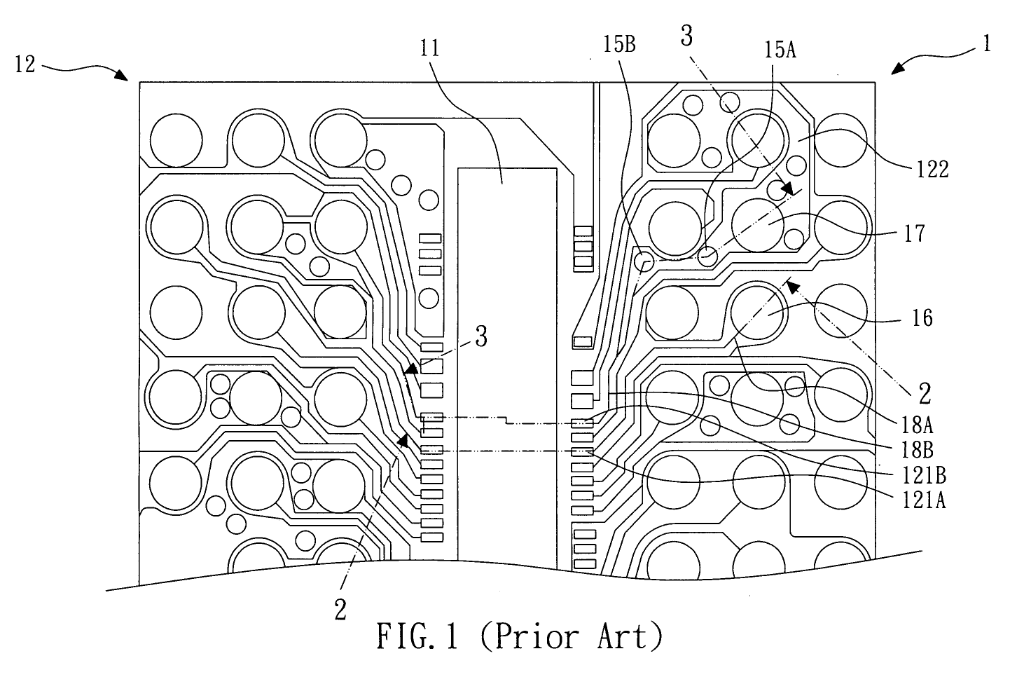

FIG. 2 is a cross-sectional view along line 2-2 in FIG. 1, wherein solder balls and wires are added;

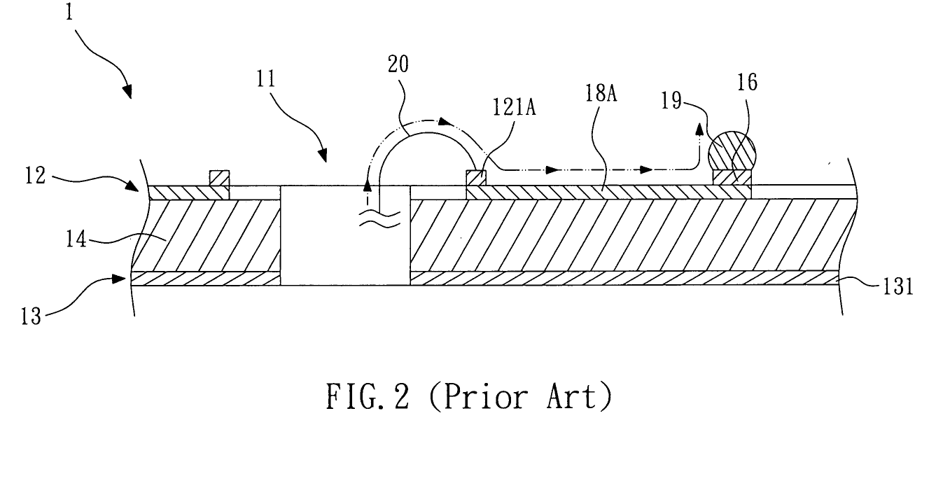

FIG. 3 is a cross-sectional view along line 3-3 in FIG. 1, wherein solder balls and wires are added;

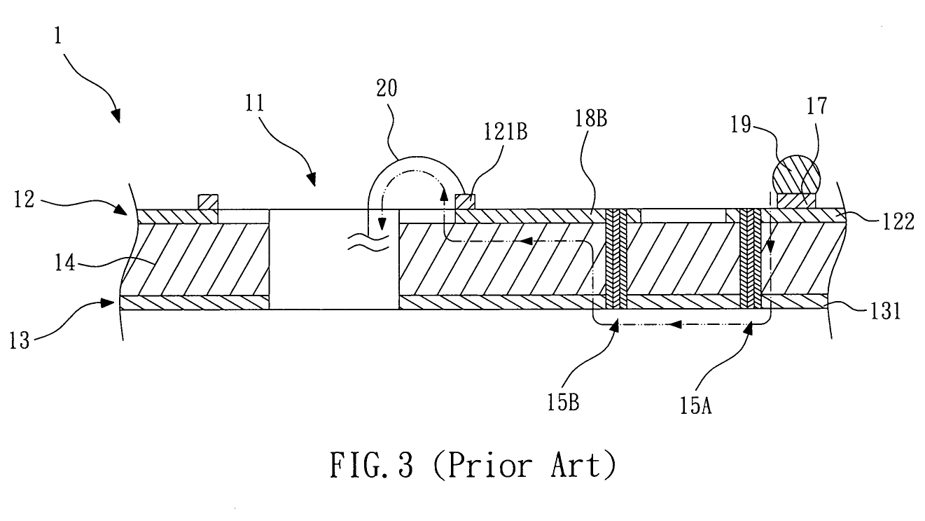

FIG. 4 is a top view of a substrate of a window ball grid array package of the present invention, wherein a solder mask is omitted;

FIG. 5 is a cross-sectional view along line 5-5 in FIG. 4, wherein solder balls and wires are added; and

FIG. 6 is a cross-sectional view along line 6-6 in FIG. 4, wherein solder balls and wires are added.

### DETAILED DESCRIPTION OF THE INVENTION

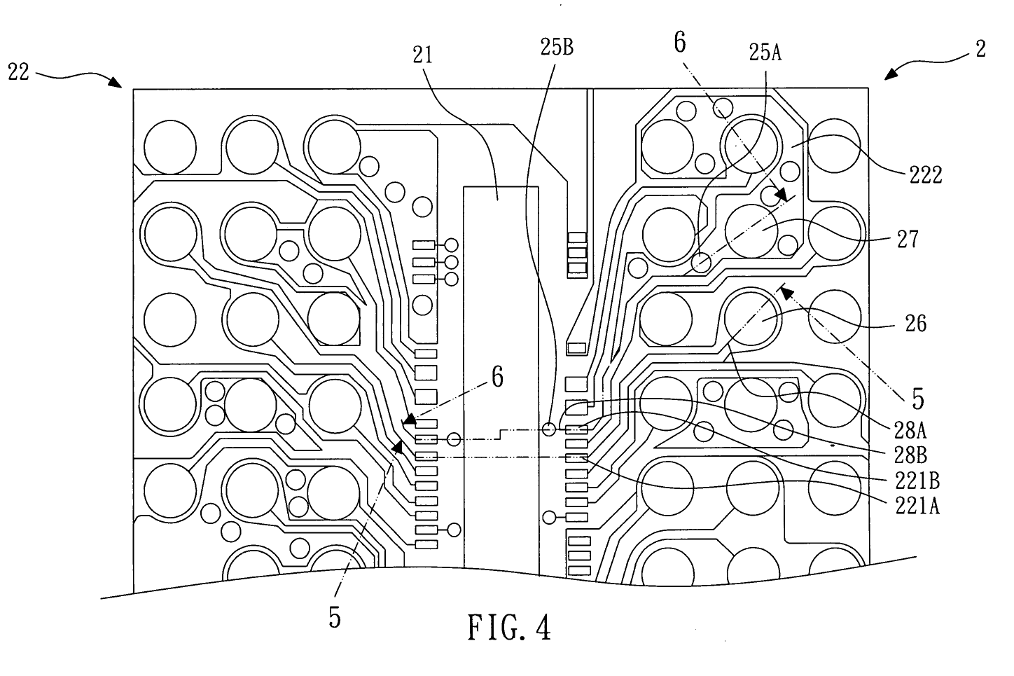

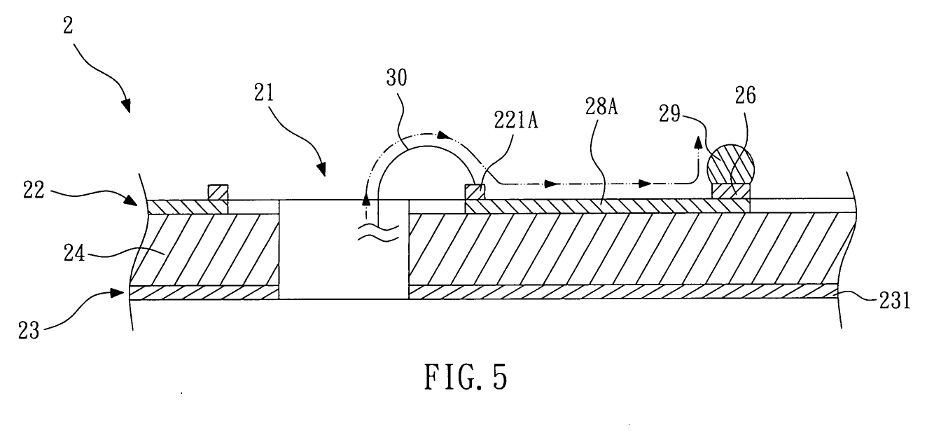

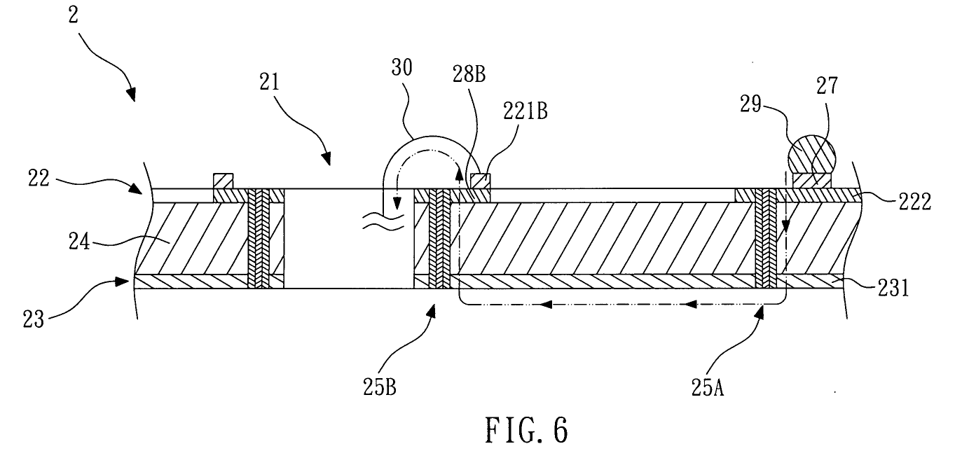

FIG. 4 shows a top view of a substrate of a window ball grid array package of the present invention, wherein a solder mask is omitted. FIG. 5 shows a cross-sectional view along line 5-5 in FIG. 4, wherein solder balls and wires are added. FIG. 6 shows a cross-sectional view along line 6-6 in FIG. 4, wherein solder balls and wires are added. The substrate 2 comprises at least one window 21, a first conductive layer 22, a second conductive layer 23 (as shown in FIGS. 5 and 6), a dielectric layer 24 (as shown in FIGS. 5 and 6), a plurality of first vias 25A and a plurality of second vias 25B.

The window 21 penetrates the substrate 2. In the embodiment, the window 21 is rectangular. The first conductive layer 22 has at least one first power/ground plane 222 and a plurality of fingers (a plurality of first fingers 221A and a plurality of second fingers 221B). In the embodiment, the first conductive layer 22 further comprises a plurality of I/O ball pads 26, a plurality of power/ground ball pads 27 and a plurality of conductive traces (a plurality of first conductive traces 28A and a plurality of second conductive traces 28B).

In the embodiment, the material of the first power/ground plane 222 is copper. In the embodiment, the power/ground ball pads 27 are disposed on the first power/ground plane 222. A plurality of solder balls 29 (as shown in FIGS. 5 and 6) are formed on the I/O ball pads 26 and the power/ground ball pads 27. The fingers (the first fingers 221A and the second fingers 221B) are disposed at the periphery of the window 21. In the embodiment, the fingers (the first fingers 221A and the second fingers 221B) are electrically connected to a chip (not shown) by a plurality of wires 30 (as shown in FIGS. 5 and 6).

The first fingers 221A are electrically connected to the I/O ball pads 26 by the first conductive traces 28A. The second fingers 221B are electrically connected to the second vias 25B by the second conductive traces 28B. The second vias 25B are disposed between the second fingers 221B and the window 21, so that the second conductive traces 28B are disposed between the second vias 25B and the second fingers 221B. Therefore, it is not necessary to dispose any second conductive traces 28B between the power/ground ball pads 27 and the second fingers 221B.

The second conductive layer 23 has at least one second power/ground plane 231 (as shown in FIGS. 5 and 6). In the embodiment, the material of the second power/ground plane 231 is copper. The dielectric layer 24 is disposed between the first conductive layer 22 and the second conductive layer 23. The first vias 25A penetrate the dielectric layer 24 and electrically connect the first power/ground plane 222 to the second power/ground plane 231. The second vias 25B penetrate the dielectric layer 24. The second vias 25B are disposed between the fingers (the first fingers 221A and the second fingers 221B) and the window 21, and electrically connect the second conductive traces 28B and the second fingers 221B to the second power/ground plane 231.

FIGS. 5 and 6 show schematic views of the substrate of a window ball grid array package of the present invention during operation. First, FIG. 5 shows a schematic view of a current of a signal. When the chip (not shown) sends out a signal, the current of the signal is transmitted to the first fingers 221A by the wires 30, then to the I/O ball pads 26 by the first conductive traces 28A, and finally out by the solder balls 29.

FIG. 6 shows a schematic view of a return current. The return current is transmitted to the power/ground ball pads 27 by the solder balls 29, and then to the second power/ground plane 231 of the second conductive layer 23 by the first power/ground plane 222 of the first conductive layer 22 and the first vias 25A. Afterward, the return current is transmitted to the first conductive layer 22 by the second vias 25B, then transmitted to the second fingers 221B by the second conductive traces 28B, and finally back to the chip by the wires 30.

In the present invention, the second vias 25B are disposed between the second fingers 221B and the window 21, and electrically connect the second fingers 221B to the second power/ground plane 231. Since the second conductive layer 23 is a good conductor with a wide area, the return current passes through a path with low impedance on the second conductive layer 23 and then the return current is transmitted to the second fingers 221B by the second vias 25B. Thus, the substrate 2 can control the characteristic impedance and increase the signal integrity.

While several embodiments of the present invention have been illustrated and described, various modifications and improvements can be made by those skilled in the art. The embodiments of the present invention are therefore described in an illustrative but not restrictive sense. It is intended that the present invention should not be limited to the particular forms as illustrated, and that all modifications which maintain the spirit and scope of the present invention are within the scope defined in the appended claims.

What is claimed is:

1. A substrate of a window ball grid array package, comprising:
at least one window, penetrating the substrate;
a first conductive layer, having a plurality of fingers and at least one first power/ground plane, wherein the fingers are disposed at the periphery of the window;
a second conductive layer, having at least one second power/ground plane;
a dielectric layer, disposed between the first conductive layer and the second conductive layer;
a plurality of first vias, penetrating the dielectric layer and electrically connecting the first power/ground plane to the second power/ground plane; and
a plurality of second vias, penetrating the dielectric layer, disposed between the fingers and the window, and electrically connecting some of the fingers to the second power/ground plane.

2. The substrate as claimed in claim 1, wherein the window is rectangular.

3. The substrate as claimed in claim 1, wherein the material of the first power/ground plane and the second power/ground plane is copper.

4. The substrate as claimed in claim 1, wherein the first conductive layer further comprises a plurality of I/O ball pads, a plurality of power/ground ball pads and a plurality of first conductive traces, and the fingers comprises a plurality of first fingers and a plurality of second fingers; the I/O ball pads are electrically connected to the first fingers by the first conductive traces, the power/ground ball pads are disposed on the first power/ground plane, and the second fingers are electrically connected to the second power/ground plane by the second vias.

5. The substrate as claimed in claim 4, wherein the first conductive layer further comprises a plurality of second conductive traces, and the second conductive traces electrically connect the second fingers to the second vias.

6. The substrate as claimed in claim 4, wherein the fingers are electrically connected to a chip, and a plurality of solder balls are formed on the I/O ball pads and the power/ground ball pads.
